(19) United States
(12) Patent Application Publication
(10) Pub. No.: US 2026/0188396 A1
(43) Pub. Date: Jul. 2, 2026

(54) DYNAMICALLY ADJUSTING CLOCK FREQUENCIES

(71) Applicant: Micron Technology, Inc., Boise, ID (US)

(72) Inventors: Qiuying Zhao, San Jose, CA (US); Tomoko Ogura Iwasaki, San Jose, CA (US); Zheng Wang, Louisville, CO (US); Krupenkumar Amin, Folsom, CA (US); Jihye Gale Shin, Palo Alto, CA (US); Biagio Iorio, Luco Dei Marsi (IT)

(21) Appl. No.: 19/429,968

(22) Filed: Dec. 22, 2025

Related U.S. Application Data
(60) Provisional application No. 63/740,058, filed on Dec. 30, 2024.

(51) Int. Cl. G11C 16/32; G11C 16/10; G11C 16/34

(52) U.S. Cl. CPC G11C 16/32; G11C 16/102; G11C 16/3418

(57) ABSTRACT

Methods, systems, and devices for dynamically adjusting clock frequencies are described. A memory system may dynamically adjust a frequency of an internal clock according to the temperature of the memory system. The memory system may operate the internal clock according to a first frequency, where the first frequency is associated with a first temperature threshold. In response to receiving a programming command, the memory system may determine whether to operate the memory system at a second frequency or the first frequency based on whether a temperature of the memory system satisfies a second threshold, where the second frequency may be faster than the first frequency. Accordingly, if the temperature of the memory system satisfies the threshold, the memory system may operate the internal clock according to the second frequency. Alternatively, the memory system may operate the internal clock according to the first frequency.

### CROSS REFERENCE

The present Application for Patent claims priority to U.S. patent application Ser. No. 63/740,058 by Zhao et al., entitled “DYNAMICALLY ADJUSTING CLOCK FREQUENCIES,” filed Dec. 30, 2024, which is assigned to the assignee hereof, and which is expressly incorporated by reference in its entirety herein.

### TECHNICAL FIELD

The following relates to one or more systems for memory, including dynamically adjusting clock frequencies.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports dynamically adjusting clock frequencies in accordance with examples as disclosed herein.

FIG. 2 shows an example of a process flow that supports dynamically adjusting clock frequencies in accordance with examples as disclosed herein.

FIGS. 3A and 3B show examples of systems that support dynamically adjusting clock frequencies in accordance with examples as disclosed herein.

FIG. 4 shows a block diagram of a memory system that supports dynamically adjusting clock frequencies in accordance with examples as disclosed herein.

FIG. 5 shows a flowchart illustrating a method or methods that support dynamically adjusting clock frequencies in accordance with examples as disclosed herein.

### DETAILED DESCRIPTION

Some memory systems may experience performance degradation when subjected to relatively high and/or low temperatures. For example, a memory system may operate within a system (e.g., vehicle systems, among others) that experiences a range of temperatures (e.g., −40 degrees Celsius (C.) to 130 degrees C.). In such examples, to maintain reliability at the high temperatures (e.g., 130 degrees C. or above), the memory system may decrease the frequency of an internal clock of the memory system. However, slowing the frequency of the internal clock may result in increased programming times (e.g., increased programming latency), which may reduce the efficiency at which the memory system operates. Additionally, by adjusting the frequency of the internal clock according to a single temperature metric (e.g., adjusting at a high temperature), the memory system may similarly experience reduced efficiency (e.g., due to having less granularity in operating frequencies), among other challenges. Thus, techniques may be desired to maintain or improve the efficiency of the memory system, while also maintaining the reliability of the memory system at relatively high temperatures.

The techniques, methods, and devices described herein may enable the memory system to dynamically adjust the frequency of an internal clock according to one or more temperature thresholds. For example, the memory system may operate an internal clock according to a first frequency (e.g., default frequency), where the first frequency is associated with (e.g., tuned for or based on) a first temperature (e.g., a default temperature,130 degrees C. or above). By operating the internal clock at the first frequency, the memory system may maintain the reliability of operations at the memory system during runtime, including at higher temperatures. In response to receiving a programming command, the memory system (e.g., via firmware executed by a memory system controller) may determine whether to operate the memory system at a second frequency or the first frequency based on whether a temperature of the memory system satisfies a threshold (e.g., 100 degrees C., 90 degrees C., 85 degrees C., among other examples), where the second frequency may be faster than the first frequency.

Accordingly, if the memory system determines that the temperature does satisfy the threshold, the memory system may operate the internal clock according to the second frequency during a programming operation, thereby decreasing programming time at the memory system during operations, for example, at lower temperatures. Alternatively, if the memory system determines that the temperature does not satisfy the threshold (e.g., is greater than the threshold), the memory system may perform the programming operation according to the first frequency, thereby maintaining reliability of the operations while operating, for example, at higher temperatures.

In such examples, the memory system may maintain a mapping between temperatures (e.g., temperature ranges or temperature threshold) and frequencies of the internal clock, such that the memory system 110 may identify the frequency of the internal clock based on a temperature of the memory system. In this way, the memory system may tailor (e.g., adjust) the frequency of the internal clock, in response to the temperature of the memory system increasing or decreasing. By tailoring the frequency of the internal clock according to the temperature of the memory system, the memory system may experience an improvement in the efficiency (e.g., reduce programming times) of the memory system while operating at lower temperatures, while also maintaining reliable operations at relatively high temperatures.

In addition to applicability in memory systems as described herein, techniques for dynamically adjusting clock frequencies may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds by increasing or decreasing clock frequencies according to the temperature of the memory system, which may decrease processing or latency times, improve response times, or otherwise improve user experience, among other benefits.

Features of the disclosure are illustrated and described in the context of systems, devices, and circuits. Features of the disclosure are further illustrated and described in the context of process flows, systems, and flowcharts.

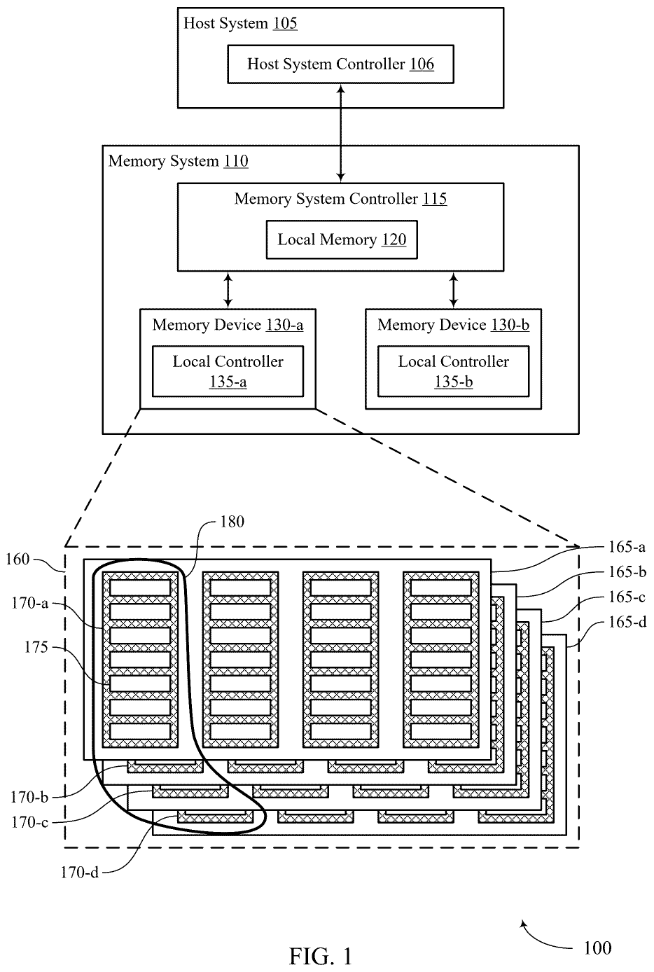

FIG. 1 shows an example of a system 100 that supports dynamically adjusting clock frequencies in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, the memory system 110 may operate within an application that has various quality and reliability metrics, where such metrics may be based on the operating conditions experienced by the memory system 110. As an illustrative example, the memory system 110 may be implemented into an automotive environment, where the memory system 110 may be designed to meet various quality and reliability metrics while operating within an extended temperature range (e.g., −40 degrees C. to 105 degrees C., 115 degrees C., 125 degrees C., or 130 degrees C.), while accounting for cross temperature access operations (e.g., access operations at wide ranges of temperature, such as −40 degrees C. to 105 degrees C.), during a beginning of life of the memory system 110, and during an end of life of the memory system 110.

With the rise of electric vehicles (EVs), the various quality and reliability metrics expected to be met by the memory system 110 may evolve. Additionally, some emerging EV manufacturers and suppliers may not have the same memory standards (e.g., quality and reliability metrics). That is, each EV manufacturer and supplier may utilize different models or have operating conditions which differ, thereby allowing for flexible memory solutions. As a result, some quality and reliability metrics may be different for various EV applications. Such quality and reliability metrics, however, affect yield, testing time, and cost, where extensive testing increases production time and costs, as well as automotive memory performance and power consumption. Balancing performance with power consumption may improve the overall functionality of the EV. As such, the shift towards EV may introduce different considerations within the design of memory systems 110, prompting different approaches to the design of memory systems 110.

Additionally, the memory system 110 may operate within a system that utilizes artificial intelligence (AI), leading to various quality and reliability metrics. For example, with the advent of AI, the implementation of higher storage performance, improved bandwidth, among other considerations, have become intensified for memory systems 110. That is, some implementations of a memory system 110 in AI applications may lead to prioritization of performance over other specifications.

As described herein, the memory system 110 may be designed to satisfy various quality and reliability metrics while operating within an extended temperature range (e.g., up to 130 degrees C.). However, the memory system 110 may experience performance degradation when subjected to such high temperatures. To maintain reliability at the high temperatures (e.g., 130 degrees C. or above), the memory system 110 may decrease the frequency of an internal clock of the memory system 110. In one case, in response to the memory system 110 operating at the high temperature, the memory system 110 may reduce the frequency (e.g., speed) of the internal clock by 10%. In such cases, however, slowing the frequency of the internal clock may lead to increased programming times (e.g., increased programming latency), which may reduce the efficiency at which the memory system 110 operates. Additionally, by adjusting the frequency of the internal clock according to a single temperature metric, the memory system 110 may similarly experience reduced efficiency (e.g., due to having less granularity in operating frequencies). Thus, techniques may be desired to maintain or improve the efficiency of the memory system 110, while also maintaining the reliability of the memory system 110 at relatively high temperatures.

Because the memory system 110 (e.g., NAND device, eMMC device, UFS device, SSD) may not operate at such elevated temperatures for increased periods of time, the techniques described herein may enable the memory system 110 may implement dynamic adjustments of the internal clock, which may accelerate programming at nominal or lower temperature ranges, thereby improving the average programming time in the memory system 110. For example, the memory system 110 may adapt the frequency of the internal clock at lower temperatures, while operating performance demanding applications, or both, thereby enhancing programming speed without compromising the average programming time. Such dynamic adjustment to the frequency of the internal clock may balance performance with temperature ranges experienced by the memory system within a variety of applications (e.g., automotive, EV, AI, among others).

In some examples, the memory system 110 may operate the internal clock according to a first frequency (e.g., default frequency), where the first frequency is based on (e.g., tuned for) a first temperature (e.g., default temperature, 130 degrees C. or above). By operating the internal clock at the first frequency, the memory system 110 may maintain the reliability of all operations at the memory system 110 during runtime. In response to receiving a programming command, the memory system 110 (e.g., via firmware executed by the memory system controller 115) may determine whether to operate the memory system 110 at a second frequency or the first frequency based on whether a temperature of the memory system 110 satisfies a threshold (e.g., 100 degrees C., 90 degrees C., 85 degrees C.), where the second frequency may be faster than the first frequency.

Accordingly, if memory system 110 determines that the temperature does satisfy the threshold, the memory system 110 may operate the internal clock according to the second frequency during a programming operation, thereby decreasing programming times at the memory system 110 during operations at lower temperatures. Alternatively, if the memory system 110 determines that the temperature does not satisfy the threshold (e.g., is greater than the second threshold), the memory system 110 may perform the programming operation according to the first frequency, thereby maintaining reliability of the operations while operating at higher temperatures. In this way, the memory system 110 may tailor (e.g., adjust) the frequency of the internal clock, in response to the temperature of the memory system 110 changing, such as increasing or decreasing.

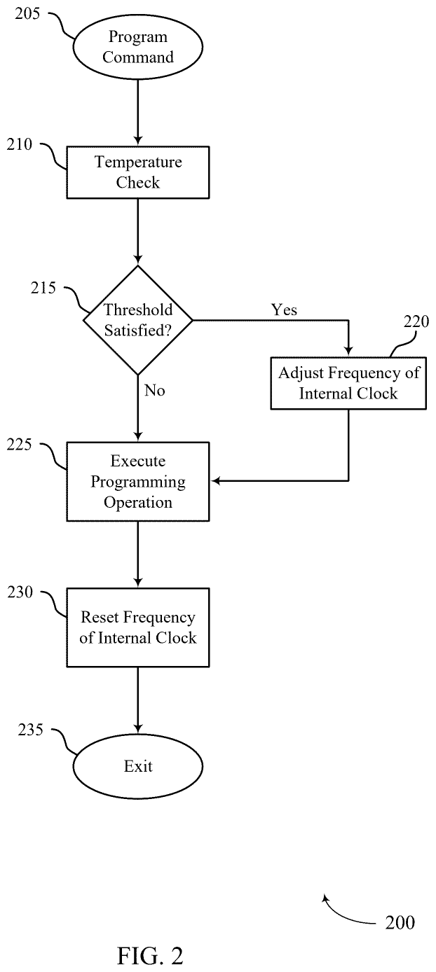

FIG. 2 shows an example of a process flow 200 that supports dynamically adjusting clock frequencies in accordance with examples as disclosed herein. Aspects of the process flow 200 may be implemented by aspects of the system 100. For example, the memory system 110, via the memory system controller 115 or a local controller 135, may perform the operations of the process flow 200. The techniques described in the context of the process flow 200 may enable the memory system 110 to dynamically adjust the frequency of an internal clock of the memory system 110.

In some cases, the memory system 110 may experience performance degradation when subjected to increased temperatures. Accordingly, to maintain reliable operations at high temperatures (e.g., 130 degrees C.), the memory system 110 may reduce the frequency of an internal clock (e.g., an internal oscillator clock, oscclk) by 10%, which may impact programming times (e.g., a duration to perform a programming operation). As described herein, the internal clock may control various timing and synchronizations within the memory system 110, such as timing and synchronization of programming operations (e.g., write and read operations), among other examples. As such, the adjustment of the frequency of the internal clock may affect timings of various operations within the memory system, including programming (e.g., write and read operations).

For example, during a program operation (e.g., writing or reading data), the memory system 110 may perform one or more operational processes (e.g., loops) to program a memory device 130, where a duration of one of these operational processes may be referred to as a loop time (e.g., tLOOP). Accordingly, the programming time may be based on a combination of the loop times of each operational process. Thus, if the memory system 110 reduces the frequency of the internal clock, the loop time of each operational process during the programming operation may increase, thereby increasing the overall programming time. Such an increased programming time may reduce the efficiency of the memory system 110, leading to poor user experience.

In accordance with the techniques described herein, the memory system 110 may dynamically adjust the frequency of the internal clock of the memory system 110 according to a temperature of the memory system 110. By doing so, at lower temperatures, the memory system 110 may accelerate memory programming (e.g., due to an increase in frequency of the internal clock), where such accelerated memory programming may lead to quicker data storage and retrieval, a reduced (e.g., balanced) average programming time, efficient memory performance across varying temperature conditions, among other advantages, while also maintaining the reliability of the memory system 110.

For example, prior to receiving a programming command, the memory system 110 may operate the internal clock according to a first frequency (e.g., a default frequency), where the first frequency accommodates (e.g., is tuned for) a first temperature (e.g., a default temperature, 130 degrees C. or above). That is, the memory system 110 may operate the internal clock according to a default frequency that is associated with relatively high temperatures (e.g., 130 degrees C. or above), such that the memory system 110 may ensure that the reliability of operations at the memory system 110 are maintained during runtime.

Accordingly, at 205, the memory system 110 may receive a programming command. In some examples, the memory system 110 may receive the programming command from the host system 105, where the programming command may be an example of a read operation, a write operation, a refresh operation, a wear-leveling operation, a garbage collection operation, or some combination of one or more operations, among other examples. Alternatively, the memory system 110 may internally generate the programming command, such as for refresh operations, garbage collection operations, wear-leveling operations, among other operations internal to the memory system 110.

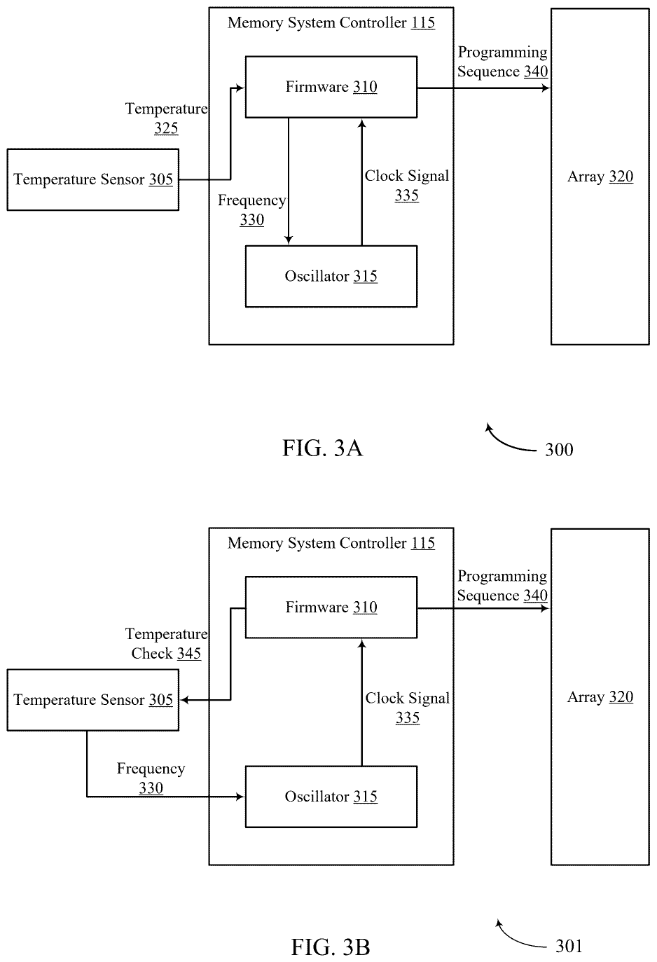

At 210, the memory system may perform a temperature check procedure in response to receiving the programming command. In some examples, in response to receiving the programming command, the memory system controller 115 may receive a temperature, for example, from a temperature sensor of the memory system 110 as part of the temperature check procedure. That is, at the beginning of a program sequence, the memory system controller 115 may check (e.g., obtain or receive) data from a temperature sensor of the memory system 110, where the data may include the temperature of the memory system 110. Such techniques may be further described herein with reference to FIG. 3A. Alternatively, in response to receiving the programming command, the memory system 110 may transmit a temperature check command to the temperature sensor, where the temperature sensor may perform the operations 215 and 220 in response to receiving the temperature check command from the memory system controller 115. Such techniques may be further described herein with reference to FIG. 3B.

At 215, the memory system 110 (e.g., either the memory system controller 115 or the temperature sensor) may determine whether the temperature of the memory system 110 satisfies one or more thresholds. In some examples, the memory system 110 may determine whether the temperature satisfies a threshold (e.g., 100 degrees Celsius), where if the temperature does satisfy (e.g., is less than) the threshold, the memory system 110 may proceed to the operations at 220. Alternatively, if the memory system determines that the temperature does not satisfy (e.g., is greater than or equal to) the threshold, the memory system 110 may proceed to the operations at 225.

In some examples, the memory system 110 (e.g., either the memory system controller 115 or the temperature sensor) may maintain a mapping (e.g., look up table) between multiple temperature thresholds and multiple frequencies. The difference between each be temperature threshold of the multiple temperature thresholds may by a fraction of a degree, one degree, two degrees, or any quantity of degrees. As such, the memory system 110 may, at 215, identify a frequency of the internal clock based on the temperature of the memory system 110 being less than one of the multiple temperature thresholds in the mapping and proceed to the operations at 220.

As an illustrative example, the memory system 110 may maintain a mapping that includes 3 temperature thresholds, such as 120 degrees C., 100 degrees C., and 80 degrees C. In such examples, the temperature threshold of 120 degrees C. may be associated with a second frequency that is faster than the default (e.g., first) frequency, while the temperature threshold of 100 degrees C. may be associated with a third frequency that is faster than the second frequency. Similarly, the temperature threshold of 80 degrees C. may be associated with a fourth frequency that is faster than the third frequency.

At 220, the memory system 110 (e.g., the memory system 110 or the temperature sensor) may adjust the frequency of the internal clock. In one example, if, at 215, the memory system 110 that the temperature of the memory system 110 satisfies the threshold, the memory system 110 may adjust the frequency of the internal clock to a second frequency that is faster than the first frequency (e.g., default frequency).

In some examples, if, at 215, the memory system 110 utilizes a mapping to identify the frequency of the internal clock based on the temperature of the memory system 110, the memory system 110 may adjust the frequency of the internal clock according to the mapping. Continuing with the illustrative example, if, at 210, the temperature of the memory system 110 is 79 degrees C., the memory system 110 may adjust the frequency of the internal clock to be the fourth frequency at 220 due to 79 degrees C. being less than 80 degrees C. Alternatively, if, at 210, the temperature of the memory system 110 is 90 degrees C., the memory system 110 may adjust the frequency of the internal clock to be the third frequency due to 90 degrees C. being less than 100 degrees C. but greater than 80 degrees C.

In some examples, to adjust the frequency of the internal clock, the memory system 110 may adjust one or more trim settings of the internal clock in order to achieve the identified frequency. In such examples, because an update to the frequency of the internal clock may impact algorithm timings, leading to different raw bit error rates (RBER) in the memory system 110 and different reliabilities at different temperatures, in some cases the memory system 110 may adjust various timings associated with operational algorithms (e.g., program algorithms, among other examples) according to the adjusted frequency of the internal clock.

At 225, the memory system 110 may execute a programming operation associated with the program command according to the frequency of the internal clock. For example, if, at 220, the frequency of the internal clock was adjusted, the memory system 110 may execute the programming operation according to the adjusted (e.g., faster) frequency. Alternatively, if, at 215, the temperature of the memory system 110 was not less than the one or more thresholds, the memory system 110 may execute the programming operation according to first frequency (e.g., default frequency).

In such examples, to execute the programming operation, the memory system controller 115 may transmit a programming sequence (e.g., array control signals) according to the frequency of the internal clock. In this way, by tailoring the frequency of the internal clock at 215 and 220, the memory system 110 may transmit the programming sequence with increased speed, thereby improving programming times at 225, thereby improving efficiency in the memory system 110.

At 230, in response to executing the programming operation, the memory system 110 may reset the frequency of the internal clock to the first frequency (e.g., default frequency), such that the memory system 110 may maintain reliability for other memory operations after execution of the programming operation. At 235, the memory system 110 may exit the programming operations and proceed to monitor for one or more additional programming commands at 205.

FIG. 3A shows an example of a system 300 that supports dynamically adjusting clock frequencies in accordance with examples as disclosed herein. Aspects of the system 300 may implement, or be implemented by, aspects of the system 100 and the process flow 200, as described herein with reference to FIGS. 1 and 2. For example, the system 300 may include a memory system controller 115, a temperature sensor 305, firmware 310, an oscillator 315 (e.g., internal clock), and an array 320 (e.g., a memory device 130). The techniques described in the context of the system 300 may enable the memory system controller 115 to adjust the frequency of the oscillator 315 according to the temperature 325 of the memory system 110.

For example, in response to receiving a programming command, the memory system controller 115 may obtain (e.g., receive, retrieve), from the temperature sensor 305, the temperature 325 of the memory system 110. In some examples, the memory system controller 115 may transmit a temperature request to the temperature sensor in response to receiving the programming command, such that the temperature sensor 305 may measure and transmit the temperature 325.

Based on receiving the temperature 325, the memory system controller 115 may, via the firmware 310 or otherwise, determine whether the temperature 325 satisfies one or more thresholds and identify the frequency 330 of the oscillator 315, as described herein with reference to the operations at 215 and 220 of FIG. 2. In some examples, the memory system controller 115 may maintain, in volatile or non-volatile memory, a mapping of multiple temperature thresholds and multiple frequencies 330, such that the memory system controller 115 identify the frequency 330 for the oscillator 315 based on the mapping, as described herein with reference to FIG. 2. Alternatively, the memory system controller 115 may compare the temperature 325 to a single threshold and determine the frequency 330 of the oscillator 315 based on the single threshold, as described herein with reference to FIG. 2.

Based on identifying the frequency 330, the memory system controller 115, via the firmware 310 and associated hardware (e.g., circuits), may update the oscillator 315 to operate according to the frequency 330, as described herein with reference to the operations at 220 of FIG. 2. For example, the memory system controller 115, via the firmware 310, may adjust one or more trim settings of the oscillator 315 to update the oscillator 315 to operate according to the frequency 330.

The oscillator 315 may operate according to the frequency 330 and produce the clock signal 335 having the frequency 330, such that the memory system controller 115 may begin the programming sequence 340 (e.g., execute the programming operation) according to the clock signal 335 from the oscillator 315. In response to completion of the programming sequence 340, the memory system controller 115 may reset the frequency of the oscillator 315 to the default frequency. In this way, the memory system controller 115 may update the frequency 330 of the oscillator 315.

FIG. 3B shows an example of a system 301 that supports dynamically adjusting clock frequencies in accordance with examples as disclosed herein. Aspects of the system 301 may implement, or be implemented by, aspects of the system 100 and the process flow 200, as described herein with reference to FIGS. 1 and 2. For example, the system 301 may include a memory system controller 115, a temperature sensor 305, firmware 310, an oscillator 315 (e.g., internal clock), and an array 320 (e.g., a memory device 130). The techniques described in the context of the system 300 may enable the temperature sensor 305 to adjust the frequency of the oscillator 315 according to the temperature 325 of the memory system 110.

For example, in response to receiving a programming command, the memory system controller 115 may transmit a temperature check 345 (e.g., a request to update the frequency 330 of the oscillator 315), where the temperature sensor 305 may, via internal circuitry and firmware, determine whether the temperature of the memory system 110 satisfies one or more thresholds and identify the frequency 330 of the oscillator 315, as described herein with reference to the operations at 215 and 220 of FIG. 2. In some examples, the temperature sensor 305 may maintain, in memory coupled with the temperature sensor 305, a mapping of multiple temperature thresholds and multiple frequencies 330, such that the temperature sensor 305 may identify the frequency 330 for the oscillator 315 based on the mapping, as described herein with reference to FIG. 2. Alternatively, the temperature sensor 305 may compare the temperature 325 to a single threshold and determine the frequency 330 of the oscillator 315 based on the single threshold, as described herein with reference to FIG. 2.

Based on identifying the frequency 330, the temperature sensor 305 may update the oscillator 315 to operate according to the frequency 330, as described herein with reference to the operations at 220 of FIG. 2. For example, the temperature sensor 305 may adjust one or more trim settings of the oscillator 315 to update the oscillator 315 to operate according to the frequency 330.

The oscillator 315 may operate according to the frequency 330 and produce the clock signal 335 having the frequency 330, such that the memory system controller 115 may begin the programming sequence 340 (e.g., execute the programming operation) according to the clock signal 335 from the oscillator 315. In response to completion of the programming sequence 340, the memory system controller 115, the temperature sensor 305, or both may reset the frequency of the oscillator 315 to the default frequency. In this way, the temperature sensor 305 may update the frequency 330 of the oscillator 315.

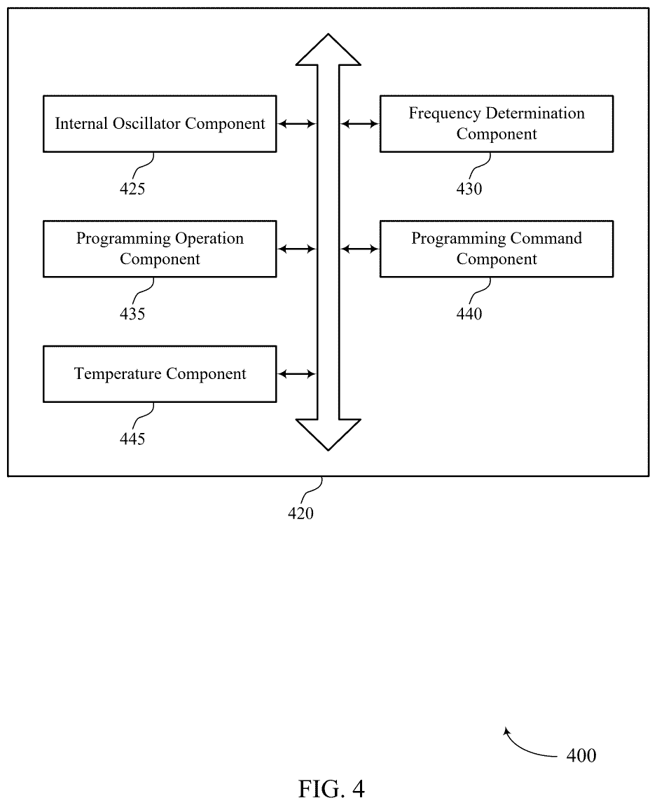

FIG. 4 shows a block diagram 400 of a memory system 420 that supports dynamically adjusting clock frequencies in accordance with examples as disclosed herein. The memory system 420 may be an example of aspects of a memory system as described with reference to FIGS. 1 through 3. The memory system 420, or various components thereof, may be an example of means for performing various aspects of dynamically adjusting clock frequencies as described herein. For example, the memory system 420 may include an internal oscillator component 425, a frequency determination component 430, a programming operation component 435, a programming command component 440, a temperature component 445, or any combination thereof. Each of these components, or components of subcomponents thereof (e.g., one or more processors, one or more memories), may communicate, directly or indirectly, with one another (e.g., via one or more buses).

The memory system 420 may support operating a memory system in accordance with examples as disclosed herein. The internal oscillator component 425 may be configured as or otherwise support a means for operating an internal clock of the memory system according to a first frequency that is associated with a first temperature. The frequency determination component 430 may be configured as or otherwise support a means for determining whether to operate the internal clock according to a second frequency or according to the first frequency in accordance with whether a temperature of the memory system satisfies a temperature threshold that is less than the first temperature. The programming operation component 435 may be configured as or otherwise support a means for executing a programming operation in accordance with the determination.

In some examples, to support determining whether to operate the internal clock according to the second frequency or according to the first frequency, the frequency determination component 430 may be configured as or otherwise support a means for determining to operate the internal clock according to the first frequency in accordance with the temperature of the memory system failing to satisfy the temperature threshold, where executing the programming operation is in accordance with the first frequency of the internal clock.

In some examples, to support determining whether to operate the internal clock according to the second frequency or according to the first frequency, the frequency determination component 430 may be configured as or otherwise support a means for determining to operate the internal clock according to the second frequency in accordance with the temperature of the memory system satisfying the temperature threshold, where executing the programming operation is in accordance with the second frequency of the internal clock.

In some examples, the internal oscillator component 425 may be configured as or otherwise support a means for adjusting a frequency of the internal clock to the first frequency in response to executing the programming operation in accordance with the second frequency.

In some examples, the frequency determination component 430 may be configured as or otherwise support a means for determining the second frequency from a mapping between a plurality of temperature thresholds and a plurality of frequencies, where determining to operate the internal clock according to the second frequency is in accordance with determining the second frequency from the mapping in accordance with the temperature of the memory system.

In some examples, the programming command component 440 may be configured as or otherwise support a means for receiving a programming command indicating the programming operation, where determining whether to operate the internal clock according to the second frequency or according to the first frequency is in response to receiving the programming command.

In some examples, the temperature component 445 may be configured as or otherwise support a means for communicating the temperature from a temperature sensor of the memory system to a controller of the memory system in response to receiving the programming command, where the controller determines whether to operate the memory system according to the first frequency or the second frequency in accordance with communicating the temperature.

In some examples, the temperature component 445 may be configured as or otherwise support a means for communicating a temperature check request from a controller of the memory system to a temperature sensor of the memory system in response to receiving the programming command, where the temperature sensor determines whether to operate the memory system according to the first frequency or the second frequency. In some examples, the frequency determination component 430 may be configured as or otherwise support a means for communicating a frequency of the internal clock from the temperature sensor to the controller in accordance with the temperature sensor determining whether to operate the memory system according to the first frequency or the second frequency.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

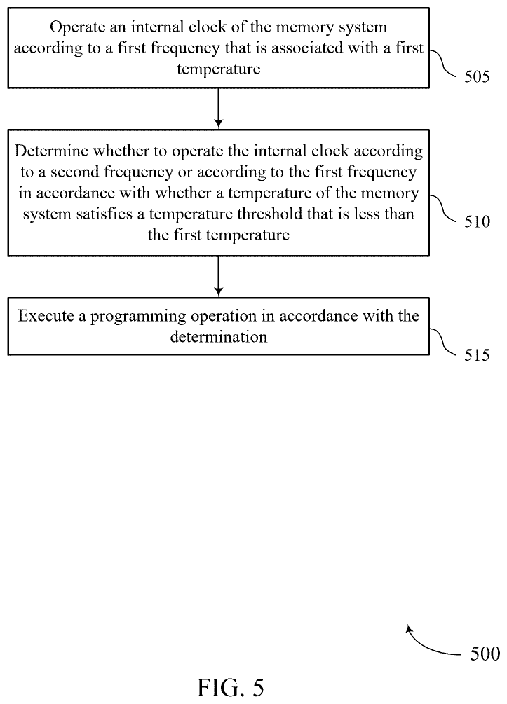

FIG. 5 shows a flowchart illustrating a method 500 that supports dynamically adjusting clock frequencies in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include operating an internal clock (e.g., the oscillators 315 of FIGS. 3A and 3B) of the memory system (e.g., the memory system 110 of FIG. 1) according to a first frequency that is associated with a first temperature, as described herein with reference to the operations 205 and 210 of FIG. 2. In some examples, aspects of the operations of 505 may be performed by an internal oscillator component 425 as described with reference to FIG. 4.

At 510, the method may include determining whether to operate the internal clock (e.g., the oscillators 315 of FIGS. 3A and 3B) according to a second frequency or according to the first frequency in accordance with whether a temperature (e.g., measured using the temperature sensors 305 of FIGS. 3A and 3B) of the memory system (e.g., the memory system 110 of FIG. 1) satisfies a temperature threshold that is less than the first temperature, as described herein with reference to the operations 210 and 215 of FIG. 2. In some examples, aspects of the operations of 510 may be performed by a frequency determination component 430 as described with reference to FIG. 4.

At 515, the method may include executing a programming operation (e.g., the programming sequence 340 of FIGS. 3A and 3B, read and/or write commands) in accordance with the determination, as described herein with reference to the operations at 225 of FIG. 2. In some examples, aspects of the operations of 515 may be performed by a programming operation component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for operating an internal clock of the memory system according to a first frequency that is associated with a first temperature; determining whether to operate the internal clock according to a second frequency or according to the first frequency in accordance with whether a temperature of the memory system satisfies a temperature threshold that is less than the first temperature; and executing a programming operation in accordance with the determination.

Aspect 2: The method, apparatus, or non-transitory computer-readable medium of aspect 1, where determining whether to operate the internal clock according to the second frequency or according to the first frequency includes operations, features, circuitry, logic, means, or instructions, or any combination thereof for determining to operate the internal clock according to the first frequency in accordance with the temperature of the memory system failing to satisfy the temperature threshold, where executing the programming operation is in accordance with the first frequency of the internal clock.

Aspect 3: The method, apparatus, or non-transitory computer-readable medium of any of aspects 1 through 2, where determining whether to operate the internal clock according to the second frequency or according to the first frequency includes operations, features, circuitry, logic, means, or instructions, or any combination thereof for determining to operate the internal clock according to the second frequency in accordance with the temperature of the memory system satisfying the temperature threshold, where executing the programming operation is in accordance with the second frequency of the internal clock.

Aspect 4: The method, apparatus, or non-transitory computer-readable medium of aspect 3, further including operations, features, circuitry, logic, means, or instructions, or any combination thereof for adjusting a frequency of the internal clock to the first frequency in response to executing the programming operation in accordance with the second frequency.

Aspect 5: The method, apparatus, or non-transitory computer-readable medium of any of aspects 3 through 4, further including operations, features, circuitry, logic, means, or instructions, or any combination thereof for determining the second frequency from a mapping between a plurality of temperature thresholds and a plurality of frequencies, where determining to operate the internal clock according to the second frequency is in accordance with determining the second frequency from the mapping in accordance with the temperature of the memory system.

Aspect 6: The method, apparatus, or non-transitory computer-readable medium of any of aspects 1 through 5, further including operations, features, circuitry, logic, means, or instructions, or any combination thereof for receiving a programming command indicating the programming operation, where determining whether to operate the internal clock according to the second frequency or according to the first frequency is in response to receiving the programming command.

Aspect 7: The method, apparatus, or non-transitory computer-readable medium of aspect 6, further including operations, features, circuitry, logic, means, or instructions, or any combination thereof for communicating the temperature from a temperature sensor of the memory system to a controller of the memory system in response to receiving the programming command, where the controller determines whether to operate the memory system according to the first frequency or the second frequency in accordance with communicating the temperature.

Aspect 8: The method, apparatus, or non-transitory computer-readable medium of any of aspects 6 through 7, further including operations, features, circuitry, logic, means, or instructions, or any combination thereof for communicating a temperature check request from a controller of the memory system to a temperature sensor of the memory system in response to receiving the programming command, where the temperature sensor determines whether to operate the memory system according to the first frequency or the second frequency and communicating a frequency of the internal clock from the temperature sensor to the controller in accordance with the temperature sensor determining whether to operate the memory system according to the first frequency or the second frequency.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: A memory system, including: one or more memory devices; and one or more controllers coupled with the one or more memory devices and configured to: operate an internal clock of the memory system according to a first frequency that is associated with a first temperature; determine whether to operate the internal clock according to a second frequency or according to the first frequency in accordance with whether a temperature of the memory system satisfies a temperature threshold that is less than the first temperature; and execute a programming operation at the one or more memory devices in accordance with the determination.

Aspect 10: The memory system of aspect 9, where the one or more controllers are further configured to: receive a programming command indicating the programming operation, where determining whether to operate the internal clock according to the second frequency or according to the first frequency is in response to receiving the programming command.

Aspect 11: The memory system of aspect 10, where the one or more controllers are further configured to: obtain, from one or more temperature sensors of the memory system, the temperature of the memory system in response to receiving the programming command, where determining whether to operate the memory system according to the first frequency or the second frequency is in accordance with obtaining the temperature from the one or more temperature sensors.

Aspect 12: The memory system of any of aspects 9 through 11, where, to determine whether to operate the internal clock according to the second frequency or according to the first frequency, the one or more controllers are configured to: determine to operate the internal clock according to the first frequency in accordance with the temperature of the memory system failing to satisfy the temperature threshold, where executing the programming operation is in accordance with the first frequency of the internal clock.

Aspect 13: The memory system of any of aspects 9 through 12, where, to determine whether to operate the internal clock according to the second frequency or according to the first frequency, the one or more controllers are configured to: determine to operate the internal clock according to the second frequency in accordance with the temperature of the memory system satisfying the temperature threshold, where executing the programming operation is in accordance with the second frequency of the internal clock.

Aspect 14: The memory system of aspect 13, where the one or more controllers are further configured to: adjust a frequency of the internal clock to the first frequency in response to executing the programming operation in accordance with the second frequency.

Aspect 15: The memory system of any of aspects 13 through 14, where the one or more controllers are further configured to: determine the second frequency from a mapping between a plurality of temperature thresholds and a plurality of frequencies, where determining to operate the internal clock according to the second frequency is in accordance with determining the second frequency from the mapping in accordance with the temperature of the memory system.

Aspect 16: The memory system of aspect 15, where the mapping is stored at the one or more controllers of the memory system.

An apparatus is described. The following provides an overview of aspects of the apparatus as described herein:

Aspect 17: A memory system, including: one or more memory devices; one or more controllers coupled with the one or more memory devices and configured to: operate an internal clock of the memory system according to a first frequency that is associated with a first temperature; and one or more temperature sensors coupled with the one or more controllers and configured to: receive, from the one or more controllers, a temperature check request; and determine whether to operate the internal clock according to a second frequency or according to the first frequency in accordance with whether a temperature of the memory system satisfies a temperature threshold that is less than the first temperature.

Aspect 18: The memory system of aspect 17, where the one or more controllers are further configured to: receive a programming command; transmit, to the one or more temperature sensors, the temperature check request in response to receiving the programming command; and execute a programming operation at the one or more memory devices in accordance with the programming command and with the determination.

Aspect 19: The memory system of aspect 18, where, to determine whether to operate the internal clock according to the second frequency or according to the first frequency, the one or more temperature sensors are configured to: determine to operate the internal clock according to the first frequency in accordance with the temperature of the memory system failing to satisfy the temperature threshold; and transmit, to the one or more controllers, an indication to operate the internal clock according to the first frequency, where executing the programming operation is in accordance with the indication to operate the internal clock according to the first frequency.

Aspect 20: The memory system of any of aspects 18 through 19, where, to determine whether to operate the internal clock according to the second frequency or according to the first frequency, the one or more temperature sensors are configured to: determine to operate the internal clock according to the second frequency in accordance with the temperature of the memory system satisfying the temperature threshold; and transmit, to the one or more controllers, an indication to operate the internal clock according to the second frequency, where executing the programming operation is in accordance with the indication to operate the internal clock according to the second frequency.

Aspect 21: The memory system of aspect 20, where the one or more controllers are further configured to: adjust a frequency of the internal clock to the first frequency in response to executing the programming operation in accordance with the second frequency.

Aspect 22: The memory system of any of aspects 20 through 21, where the one or more temperature sensors are further configured to: determine the second frequency from a mapping between a plurality of temperature thresholds and a plurality of frequencies, where determining to operate the internal clock according to the second frequency is in accordance with determining the second frequency from the mapping in accordance with the temperature of the memory system.

Aspect 23: The memory system of aspect 22, where the mapping is maintained at the one or more temperature sensors of the memory system.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
one or more controllers coupled with the one or more memory devices and configured to:
operate an internal clock of the memory system according to a first frequency that is associated with a first temperature;
determine whether to operate the internal clock according to a second frequency or according to the first frequency in accordance with whether a temperature of the memory system satisfies a temperature threshold that is less than the first temperature; and
execute a programming operation at the one or more memory devices in accordance with determining whether to operate the internal clock according to the second frequency or according to the first frequency.

2. The memory system of claim 1, wherein the one or more controllers are further configured to:
receive a programming command indicating the programming operation, wherein determining whether to operate the internal clock according to the second frequency or according to the first frequency is in response to receiving the programming command.

3. The memory system of claim 2, wherein the one or more controllers are further configured to:
obtain, from one or more temperature sensors of the memory system, the temperature of the memory system in response to receiving the programming command, wherein determining whether to operate the memory system according to the first frequency or the second frequency is in accordance with obtaining the temperature from the one or more temperature sensors.

4. The memory system of claim 1, wherein, to determine whether to operate the internal clock according to the second frequency or according to the first frequency, the one or more controllers are configured to:
determine to operate the internal clock according to the first frequency in accordance with the temperature of the memory system failing to satisfy the temperature threshold, wherein executing the programming operation is in accordance with the first frequency of the internal clock.

5. The memory system of claim 1, wherein, to determine whether to operate the internal clock according to the second frequency or according to the first frequency, the one or more controllers are configured to:
determine to operate the internal clock according to the second frequency in accordance with the temperature of the memory system satisfying the temperature threshold, wherein executing the programming operation is in accordance with the second frequency of the internal clock.

6. The memory system of claim 5, wherein the one or more controllers are further configured to:
adjust a frequency of the internal clock to the first frequency in response to executing the programming operation in accordance with the second frequency.

7. The memory system of claim 5, wherein the one or more controllers are further configured to:
determine the second frequency from a mapping between a plurality of temperature thresholds and a plurality of frequencies, wherein determining to operate the internal clock according to the second frequency is in accordance with determining the second frequency from the mapping in accordance with the temperature of the memory system.

8. The memory system of claim 7, wherein the mapping is stored at the one or more controllers of the memory system.

9. A memory system, comprising:
one or more memory devices;
one or more controllers coupled with the one or more memory devices and configured to:
operate an internal clock of the memory system according to a first frequency that is associated with a first temperature; and
one or more temperature sensors coupled with the one or more controllers and configured to:
receive, from the one or more controllers, a temperature check request; and
determine whether to operate the internal clock according to a second frequency or according to the first frequency in accordance with whether a temperature of the memory system satisfies a temperature threshold that is less than the first temperature.

10. The memory system of claim 9, wherein the one or more controllers are further configured to:
receive a programming command;
transmit, to the one or more temperature sensors, the temperature check request in response to receiving the programming command; and
execute a programming operation at the one or more memory devices in accordance with the programming command and with determining whether to operate the internal clock according to the second frequency or according to the first frequency.

11. The memory system of claim 10, wherein, to determine whether to operate the internal clock according to the second frequency or according to the first frequency, the one or more temperature sensors are configured to:
determine to operate the internal clock according to the first frequency in accordance with the temperature of the memory system failing to satisfy the temperature threshold; and
transmit, to the one or more controllers, an indication to operate the internal clock according to the first frequency, wherein executing the programming operation is in accordance with the indication to operate the internal clock according to the first frequency.

12. The memory system of claim 10, wherein, to determine whether to operate the internal clock according to the second frequency or according to the first frequency, the one or more temperature sensors are configured to:
determine to operate the internal clock according to the second frequency in accordance with the temperature of the memory system satisfying the temperature threshold; and
transmit, to the one or more controllers, an indication to operate the internal clock according to the second frequency, wherein executing the programming operation is in accordance with the indication to operate the internal clock according to the second frequency.

13. The memory system of claim 12, wherein the one or more controllers are further configured to:
adjust a frequency of the internal clock to the first frequency in response to executing the programming operation in accordance with the second frequency.

14. The memory system of claim 12, wherein the one or more temperature sensors are further configured to:
determine the second frequency from a mapping between a plurality of temperature thresholds and a plurality of frequencies, wherein determining to operate the internal clock according to the second frequency is in accordance with determining the second frequency from the mapping in accordance with the temperature of the memory system.

15. The memory system of claim 14, wherein the mapping is maintained at the one or more temperature sensors of the memory system.

16. A method for operating a memory system, comprising:
operating an internal clock of the memory system according to a first frequency that is associated with a first temperature;
determining whether to operate the internal clock according to a second frequency or according to the first frequency in accordance with whether a temperature of the memory system satisfies a temperature threshold that is less than the first temperature; and
executing a programming operation in accordance with determining whether to operate the internal clock according to the second frequency or according to the first frequency.

17. The method of claim 16, wherein determining whether to operate the internal clock according to the second frequency or according to the first frequency comprises:
determining to operate the internal clock according to the first frequency in accordance with the temperature of the memory system failing to satisfy the temperature threshold, wherein executing the programming operation is in accordance with the first frequency of the internal clock.

18. The method of claim 16, wherein determining whether to operate the internal clock according to the second frequency or according to the first frequency comprises:
determining to operate the internal clock according to the second frequency in accordance with the temperature of the memory system satisfying the temperature threshold, wherein executing the programming operation is in accordance with the second frequency of the internal clock.

19. The method of claim 18, further comprising:
adjusting a frequency of the internal clock to the first frequency in response to executing the programming operation in accordance with the second frequency.

20. The method of claim 18, further comprising:
determining the second frequency from a mapping between a plurality of temperature thresholds and a plurality of frequencies, wherein determining to operate the internal clock according to the second frequency is in accordance with determining the second frequency from the mapping in accordance with the temperature of the memory system.

21. The method of claim 16, further comprising:
receiving a programming command indicating the programming operation, wherein determining whether to operate the internal clock according to the second frequency or according to the first frequency is in response to receiving the programming command.

22. The method of claim 21, further comprising:
communicating the temperature from a temperature sensor of the memory system to a controller of the memory system in response to receiving the programming command, wherein the controller determines whether to operate the memory system according to the first frequency or the second frequency in accordance with communicating the temperature.

23. The method of claim 21, further comprising:
communicating a temperature check request from a controller of the memory system to a temperature sensor of the memory system in response to receiving the programming command, wherein the temperature sensor determines whether to operate the memory system according to the first frequency or the second frequency; and
communicating a frequency of the internal clock from the temperature sensor to the controller in accordance with the temperature sensor determining whether to operate the memory system according to the first frequency or the second frequency.
